(19) United States
(12) Patent Application Publication
(10) Pub. No.: US 2005/0127425 A1
(43) Pub. Date: Jun. 16, 2005

(54) Semiconductor device and method for fabricating the same

(75) Inventor: Hisashi Yano, Kyoto (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 10/989,378

(22) Filed: Nov. 17, 2004

(30) Foreign Application Priority Data
Nov. 21, 2003 (JP) 2003-391804

(51) Int. Cl. H01L 27/108; H01L 29/76; H01L 29/94; H01L 31/119; H01L 21/20

(52) U.S. Cl. 257/306; 438/396

(57) ABSTRACT

A semiconductor device includes a lower electrode having a bend in its cross-section, a capacitor dielectric film of a ferroelectric deposited on the top face of the lower electrode and an upper electrode deposited on the top face of the capacitor dielectric film. The upper electrode is deposited by chemical vapor deposition.

### CROSS-REFERENCE TO RELATED APLICATIONS

This application claims priority under 35 U.S.C. §119 on Patent Application No. 2003-391804 filed in Japan on Nov. 21, 2003, the entire contents of which are hereby incorporated by reference.

### BACKGROUND OF THE INVENTION

The present invention relates to a semiconductor device including a capacitor, and more specifically, a semiconductor device including a capacitor using, as a capacitor dielectric film, a ferroelectric in a three-dimensional shape, and a method for fabricating the semiconductor device.

Recently, there are increasing demands for refinement of devices also in the field of what is called a ferroelectric memory device including a capacitor using a ferroelectric as a capacitor dielectric film.

In a conventional method for coating a ferroelectric film through application, however, the ferroelectric film can be formed merely on a flat plane, and therefore, there is a limit in refinement of memory cells. In order to solve this problem, a method for depositing a ferroelectric film through chemical vapor deposition (CVD) applicable to a portion with a level difference has been studied, and a variety of examinations have been made on reduction of a cell area by three-dimensionally forming a memory cell.

Now, a capacitor used in a conventional ferroelectric memory device and a method for fabricating the capacitor will be described with reference to the accompanying drawings (see, for example, Japanese Laid-Open Patent Publication No. 2001-217408).

FIG. 8 shows the cross-sectional structure of the conventional capacitor. As shown in FIG. 8, a first barrier layer 101 of titanium aluminum nitride (TiAlN), a second barrier layer 102 of iridiium (Ir) and a third barrier layer 103 of iridium oxide (IrO₂) are successively formed in this order in the upward direction, and these three barrier layers 101, 102 and 103 are covered with an underlying dielectric film 104 of silicon oxide (SiO₂).

An opening 104a for exposing the third barrier layer 103 is formed in the underlying dielectric film 104, and a capacitor 108 composed of a lower electrode 105 made of multilayered films of iridium oxide (IrO₂) and platinum (Pt), a capacitor dielectric film 106 of a ferroelectric of, for example, strontium bismuth tantalate (SBT) and an upper electrode 107 of platinum is formed so as to cover the underlying dielectric film 104 in the periphery, on the bottom and on the inner wall of the opening 104a. At this point, the capacitor dielectric film 106 is deposited by the CVD, and the lower electrode 105 and the upper electrode 107 are deposited by sputtering.

A method for fabricating the ferroelectric capacitor having the aforementioned structure is shown in FIG. 9.

First, a first barrier layer 101, a second barrier layer 102 and a third barrier layer 103 are successively formed in an upper portion of a semiconductor substrate. Subsequently, an underlying dielectric film 104 is formed so as to cover the barrier layers 101, 102 and 103, and an opening 104a for exposing the third barrier layer 103 is formed in the underlying dielectric film 104.

Next, in step ST201 of FIG. 9, a lower electrode 105 made of multilayered films of iridium oxide and platinum is deposited by the sputtering. Then, in step ST202, patterning is performed through lithography and dry etching for removing a portion of the lower electrode 105 deposited outside the periphery of the opening 104a.

Next, in step ST203, a capacitor dielectric film 106 of SBT with a thickness of approximately 60 nm is deposited by the CVD.

Thereafter, in step ST204, an upper electrode 107 of platinum is deposited on the capacitor dielectric film 106 by the sputtering, and in step ST205, the upper electrode 107 is patterned through the lithography and the dry etching.

Next, in step ST206, annealing is performed at a temperature of approximately 775° C. in an oxygen atmosphere for 60 seconds, so as to crystallize the SBT included in the capacitor dielectric film.

The conventional method for fabricating the ferroelectric capacitor has, however, a problem that the shape of the upper electrode 107 is spoiled, and more specifically, is broken during the annealing performed for crystallizing the ferroelectric included in the capacitor dielectric film 106.

### SUMMARY OF THE INVENTION

The present inventor has variously examined the reason why the upper electrode is thus broken, resulting in finding that it is because the upper electrode 107 of platinum largely shrinks while annealing the ferroelectric. In particular, thermal stress tends to be collected in a corner portion (a bend) of the upper electrode 107 and hence such a portion is easily broken, which is serious for the ferroelectric capacitor in a three-dimensional shape. When the upper electrode 107 is thus broken, there arises a problem that a memory cell including the ferroelectric capacitor cannot attain a sufficiently high electric characteristic.

An object of the invention is overcoming this conventional problem by preventing the break of the upper electrode of the ferroelectric capacitor in a three-dimensional shape.

In order to achieve the object, the present invention is practiced in the following three aspects:

In the first aspect, a capacitor dielectric film and an upper electrode in a three-dimensional shape are deposited by chemical vapor deposition. In the second aspect, annealing of a ferroelectric is performed over a plurality of times after forming the upper electrode. In the third aspect, the annealing of the ferroelectric is performed with the formed upper electrode covered with a dielectric film.

Specifically, the semiconductor device of this invention includes a lower electrode having a bend in a cross-section thereof; a capacitor dielectric film made of a ferroelectric formed along a top face of the lower electrode; and an upper electrode formed along a top face of the capacitor dielectric film, and the upper electrode is formed by chemical vapor deposition.

In the semiconductor device of this invention, since the upper electrode is formed by the chemical vapor deposition, the film quality of the upper electrode is made more dense, and hence the upper electrode minimally shrinks during annealing of the capacitor dielectric film. Therefore, the upper electrode having a bend in a cross-section thereof, namely, having a three-dimensional shape, can be prevented from being broken (rent).

In the semiconductor device of the invention, the capacitor dielectric film is preferably formed by chemical vapor deposition.

The first method for fabricating a semiconductor device of this invention includes the steps of forming an underlying film having a concave or convex on a top face thereof; forming a lower electrode on the underlying film along the concave or convex; forming a capacitor dielectric film made of a ferroelectric on and along the lower electrode; and forming an upper electrode by chemical vapor deposition on and along the capacitor dielectric film.

In the first method for fabricating a semiconductor device, since the upper electrode is formed by the chemical vapor deposition, the film quality of the upper electrode is made more dense than that of a film deposited by, for example, sputtering. Therefore, the upper electrode minimally shrinks during the annealing of the capacitor dielectric film, and hence, the upper electrode can be prevented from being broken.

In the first method for fabricating a semiconductor device, the capacitor dielectric film is preferably formed by chemical vapor deposition.

In the first method for fabricating a semiconductor device, the upper electrode is preferably made of platinum and deposited at a temperature not less than 300° C in the step of forming an upper electrode.

The second method for fabricating a semiconductor device of this invention includes the steps of forming an underlying film having a concave or convex on a top face thereof; forming a lower electrode on the underlying film along the concave or convex; forming a capacitor dielectric film made of a ferroelectric on and along the lower electrode; forming an upper electrode on and along the capacitor dielectric film; and crystallizing the capacitor dielectric film in a stepwise manner through a plurality of times of annealing of the capacitor dielectric film after forming the upper electrode.

In the second method for fabricating a semiconductor device, the annealing of the capacitor dielectric film performed after depositing the upper electrode is carried out over a plurality of times so as to crystallize the capacitor dielectric film in a stepwise manner. Therefore, the upper electrode does not shrink at a time but shrinks in a stepwise manner, and hence, the upper electrode can be prevented from being broken.

In the second method for fabricating a semiconductor device, annealing first performed out of the plurality of times of annealing in the step of crystallizing the capacitor dielectric film in a stepwise manner is preferably performed at a temperature not less than 400° C. and not more than 650° C.

The third method for fabricating a semiconductor device of this invention includes the steps of forming an underlying film having a concave or convex on a top face thereof, forming a lower electrode on the underlying film along the concave or convex; forming a capacitor dielectric film made of a ferroelectric on and along the lower electrode; forming an upper electrode on and along the capacitor dielectric film; forming a dielectric film including silicon on the upper electrode; and crystallizing the capacitor dielectric film through annealing of the capacitor dielectric film after forming the dielectric film.

In the third method for fabricating a semiconductor device, since the capacitor dielectric film is crystallized through annealing after forming a dielectric film including silicon on the upper electrode, the upper electrode is exposed to heat used in forming the dielectric film including silicon. Therefore, since the upper electrode does not shrink at a time but shrinks in a stepwise manner, it can be prevented from being broken. In addition, the dielectric film deposited on the upper electrode works as a physical weight for the upper electrode, and hence the shrinkage of the upper electrode can be suppressed.

In the third method for fabricating a semiconductor device, the dielectric film is preferably deposited at a temperature not less than 400° C. and not more than 650° C. in the step of forming a dielectric film including silicon.

In each of the first through third methods for fabricating a semiconductor device, the ferroelectric is preferably SrBi₂(TaₓNb₁₋ₓ)₂O₉, Pb(ZrₓTi₁₋ₓ)O₃, (BaₓSr₁₋ₓ)TiO₃ or (BiₓLa₁₋ₓ)₄Ti₃O₁₂, wherein 0≦x≦1.

### BRIEF DESCRIPTION OF THE DRAWINGS

FIG. 1 is a cross-sectional view for showing the structure of a ferroelectric capacitor, that is, a semiconductor device, according to Embodiment 1 of the invention;

FIG. 2 is a graph for showing the relationships between a deposition temperature and a thermal shrinkage factor obtained in respective deposition methods employed for an upper electrode (of platinum) used in the semiconductor device of Embodiment 1;

FIG. 3 is a cross-sectional view for showing the structure of a ferroelectric capacitor, that is, a semiconductor device, according to Embodiment 2 of the invention;

FIG. 4 is a flowchart of a method for fabricating the ferroelectric capacitor corresponding to the semiconductor device of Embodiment 2;

FIG. 5 is a graph for showing the relationship between an annealing temperature employed for a capacitor dielectric film and a thermal shrinkage factor of an upper electrode (of platinum) of the semiconductor device of Embodiment 2;

FIG. 6 is a cross-sectional view for showing the structure of a ferroelectric capacitor, that is, a semiconductor device, according to Embodiment 3 of the invention;

FIG. 7 is a flowchart of a method for fabricating the ferroelectric capacitor corresponding to the semiconductor device of Embodiment 3;

FIG. 8 is a cross-sectional view for showing the structure of a conventional ferroelectric capacitor; and

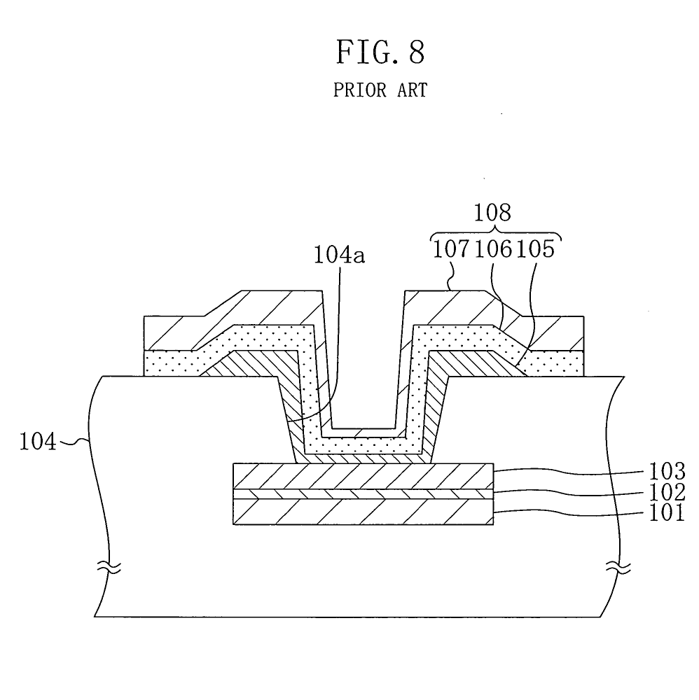

FIG. 9 is a flowchart of a method for fabricating the conventional ferroelectric capacitor.

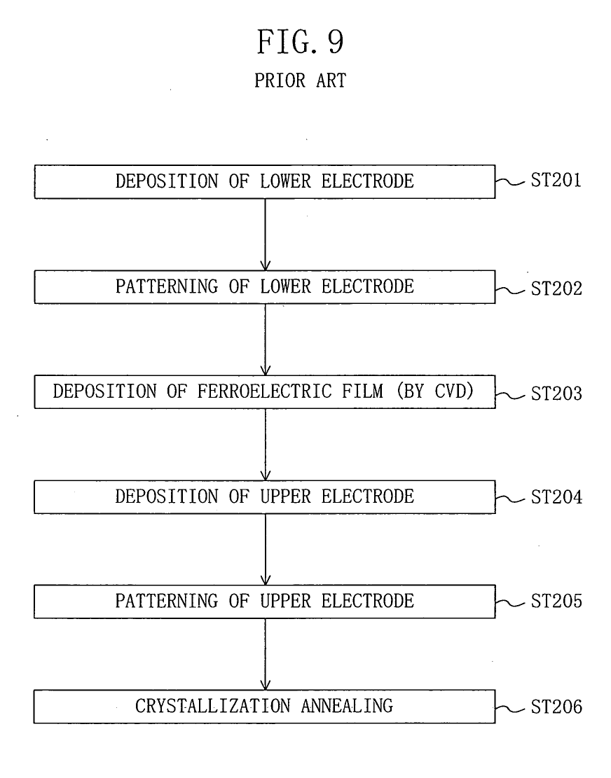

### DETAILED DESCRIPTION OF THE INVENTION

### EMBODIMENT 1

Embodiment 1 of the invention will now be described with reference to the accompanying drawings.

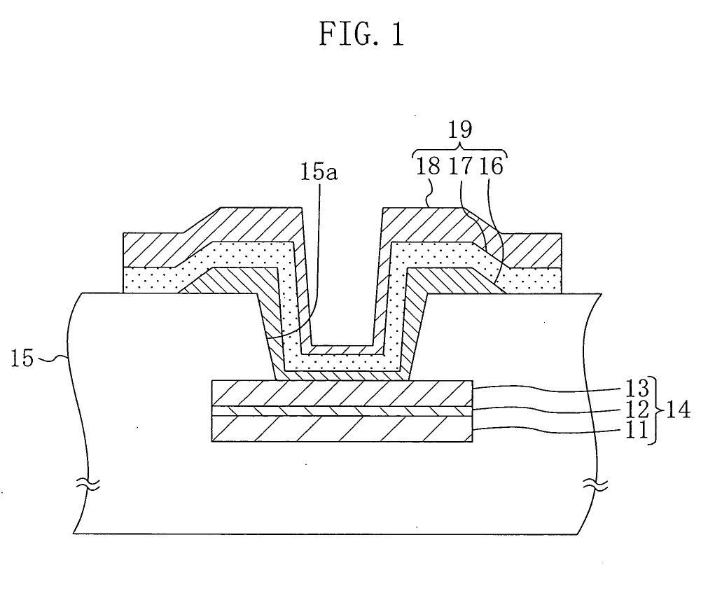

FIG. 1 shows the cross-sectional structure of a ferroelectric capacitor, that is, a semiconductor device according to Embodiment 1.

As shown in FIG. 1, on a hydrogen barrier film 14 composed of, for example, a first barrier layer 11 of titanium aluminum nitride (TiAlN) with a thickness of 100 nm, a second barrier layer 12 of iridium (Ir) with a thickness of 50 nm and a third barrier layer 13 of iridium oxide (IrO₂) with a thickness of 100 nm formed in this order in the upward direction, a capacitor 19 in a three-dimensional shape, namely, having a concave cross-section with bends in bottom and upper portions thereof, is formed.

The hydrogen barrier film 14 is buried in an underlying dielectric film 15 made of silicon oxide (SiO₂) or including silicon oxide as a principal component, and an opening 15a with a diameter of, for example, 300 nm is formed in the underlying dielectric film 15 for exposing the third barrier layer 13. The capacitor 19 includes a lower electrode 16 made of multilayered films of iridium oxide (IrO₂) with a thickness of 100 nm and platinum (Pt) with a thickness of 50 nm through 100 nm and preferably of 50 nm, a capacitor dielectric film 17 of a ferroelectric such as strontium bismuth tantalate (SrBi₂Ta₂O₉; hereinafter referred to as the SBT) with a thickness of approximately 60 nm and an upper electrode 18 of platinum with a thickness of 50 nm through 100 nm and preferably of 50 nm, which are successively deposited in this order in the upward direction so as to cover the periphery, bottom and inner wall of the opening 15a.

The capacitor dielectric film 17 is deposited by CVD, the lower electrode 16 is deposited by sputtering or the CVD, and the upper electrode 18 is deposited by the CVD.

It is noted that a contact plug for electrically connecting a semiconductor substrate not shown to the lower electrode 16 of the capacitor 19 may be provided below the hydrogen barrier film 14.

Now, the reason why the upper electrode 18 of platinum is deposited by the CVD in Embodiment I will be described. As described above, the present inventor has found that the upper electrode is broken in the conventional fabrication method because platinum deposited by the sputtering has a relatively large thermal shrinkage factor.

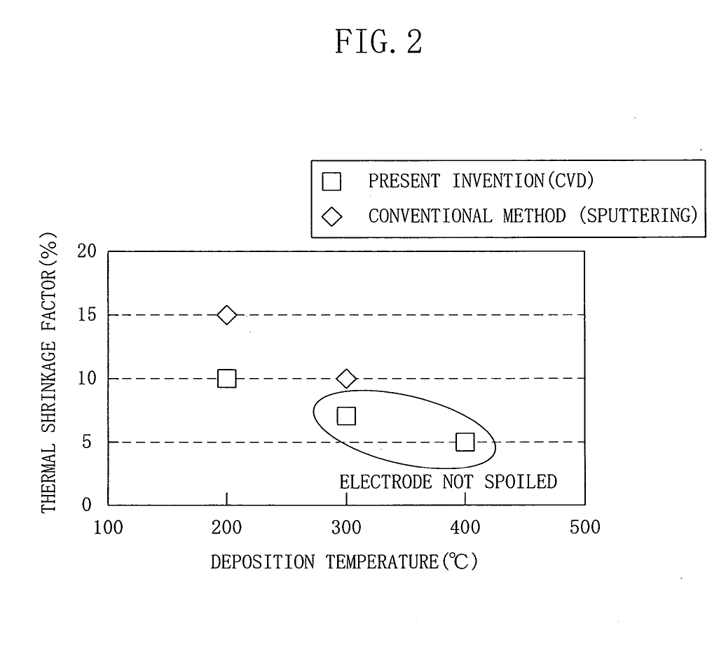

FIG. 2 shows the relationships between a deposition temperature and a thermal shrinkage factor of platinum obtained in the respective deposition methods. At this point, it is assumed that the platinum is annealed after the deposition at a temperature of 775° C. in an oxygen atmosphere for 60 seconds.

In a conventional capacitor, the upper electrode 107 is deposited by the sputtering performed at a temperature of approximately 200° C. In this case, it is understood from FIG. 2 that the platinum shrinks by approximately 15% through the annealing.

On the other hand, in the case where the upper electrode 107 is deposited by the CVD performed at a temperature of approximately 200° C., the platinum shrinks by approximately 10%, which is lower by 5% than that attained by the sputtering. Furthermore, in the case where the deposition temperature of the platinum film is increased in employing the CVD, the thermal shrinkage factor is approximately 7% or less when the deposition temperature is 300° C. or more, and it is confirmed that the upper electrode 18 is not broken in this case. In other words, when the thermal shrinkage factor of the upper electrode 18 is lower than 10%, the upper electrode 18 can be prevented from being broken. This phenomenon seems to occur because the platinum film deposited by the CVD attains a dense film quality and the thermal shrinkage minimally occurs in the platinum film with a dense film quality.

In Embodiment 1, it is confirmed that the effect of the invention can be attained no matter whether the lower electrode 16 of platinum or the like is deposited by the sputtering or the CVD. In the case where the lower electrode 16 is made of platinum or the like deposited by the sputtering, it is apprehended that the lower electrode 16 is broken in the same manner as the upper electrode 18. However, the lower electrode 16 is not broken because it is substantially annealed through the annealing performed for depositing the capacitor dielectric film 17 and is physically pressed by the capacitor dielectric film 17.

### EMBODIMENT 2

Embodiment 2 of the invention will now be described with reference to the accompanying drawings.

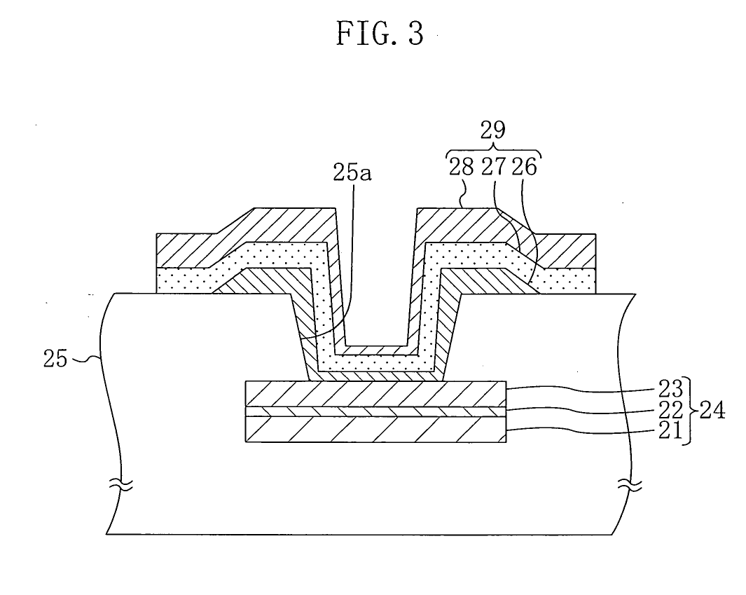

FIG. 3 shows the cross-sectional stricture of a ferroelectric capacitor, that is, a semiconductor device of Embodiment 2.

As shown in FIG. 3, on a hydrogen barrier film 24 composed of, for example, a first barrier layer 21 of titanium aluminum nitride (TiAlN) with a thickness of 100 nm, a second barrier layer 22 of iridium (Ir) with a thickness of 50 nm and a third barrier layer 23 of iridium oxide (IrO₂) with a thickness of 100 nm deposited in this order in the upward direction, a capacitor 29 in a three-dimensional shape, namely, having a concave cross-section with bends in bottom and upper portions thereof, is formed.

The hydrogen barrier film 24 is buried in an underlying dielectric film 25 made of silicon oxide (SiO₂) or including silicon oxide as a principal component, and an opening 25a with a diameter of, for example, 300 nm is formed in the underlying dielectric film 25 for exposing the third barrier layer 23. The capacitor 29 includes a lower electrode 26 made of multilayered films of iridium oxide (IrO₂) with a thickness of 100 nm and platinum (Pt) with a thickness of 50 nm through 100 nm and preferably of 50 nm, a capacitor dielectric film 27 of a ferroelectric such as strontium bismuth tantalate (SBT) with a thickness of approximately 60 nm, and an upper electrode 28 of platinum with a thickness of 50 nm through 100 nm and preferably of 50 nm, which are successively deposited in this order in the upward direction so as to cover the periphery, bottom and inner wall of the opening 25a. As a characteristic of Embodiment 2, the capacitor dielectric film 27 is crystallized through two annealing processes of preliminary annealing and regular annealing.

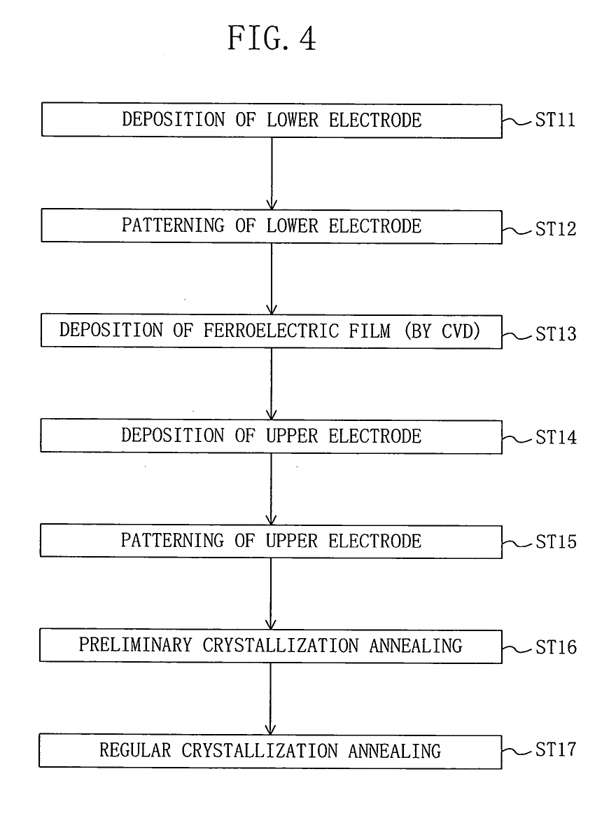

Now, a method for fabricating the ferroelectric capacitor having the aforementioned structure will be described with reference to a fabrication flowchart of FIG. 4.

First, a first barrier layer 21 of TiAlN, a second barrier layer 22 of Ir and a third barrier layer 23 of IrO₂ are successively deposited by, for example, the CVD in an upper portion of a semiconductor substrate (not shown), and these barrier layers are patterned through dry etching using a gas including chlorine (Cl₂), so as to form a hydrogen barrier film 24 composed of the first barrier layer 21, the second barrier layer 22 and the third barrier layer 23. Subsequently, an underlying dielectric film 25 is deposited by plasma CVD so as to cover the hydrogen barrier film 24, and an opening 25a for exposing the third barrier layer 23 is formed in the underlying dielectric film 25 through lithography and dry etching using an etching gas including fluorocarbon.

Next, in step ST11 of FIG. 4, a lower electrode 26 made of multilayered films of IrO₂ and Pt is deposited by the sputtering, and in step ST12, a portion of the lower electrode 26 deposited outside the periphery of the opening 25a is removed by patterning through the lithography and the dry etching.

Then, in step ST13, a capacitor dielectric film 27 of SBT is deposited by the CVD.

Next, in step ST14, an upper electrode 28 of platinum is deposited on the capacitor dielectric film 27 by the sputtering, and thereafter, in step ST15, the deposited upper electrode 28 and capacitor dielectric film 27 are patterned through the lithography and the dry etching, resulting in obtaining a capacitor 29. At this point, the etching gas used for the upper electrode 28 is a gas including chlorine (Cl₂) and the etching gas used for the capacitor dielectric film 27 is a gas including chlorine and fluorine:

Then, in step ST16, the capacitor 29 is subjected to preliminary annealing (first annealing) at a temperature of approximately 500° C. in an oxygen atmosphere for 60 seconds, so as to preliminarily crystallize the SBT included in the capacitor dielectric film 27. Subsequently, in step ST17, the capacitor 29 is subjected to regular annealing (second annealing) at a temperature of approximately 775° C. in an oxygen atmosphere for 60 seconds, so as to completely crystallize the SBT.

Now, the reason why the preliminary crystallization annealing of step ST16, that is, the characteristic of this embodiment, is performed will be described.

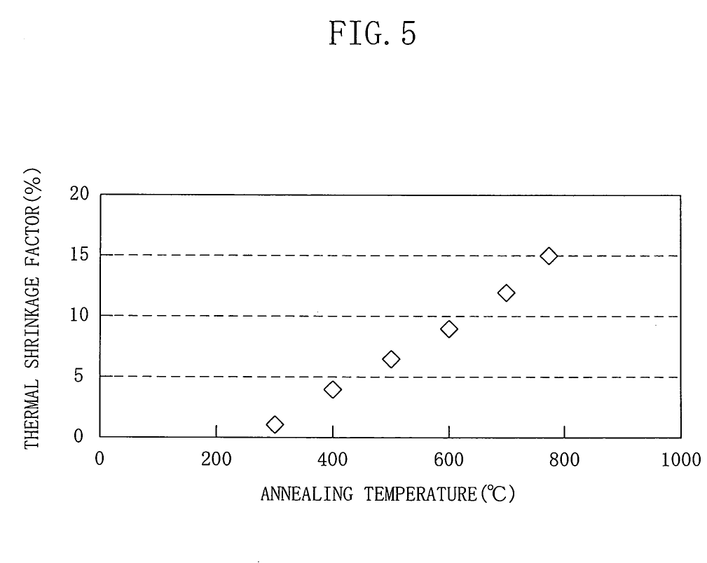

FIG. 5 shows the relationship between an annealing temperature and a thermal shrinkage factor obtained when platinum is deposited by the sputtering.

As is understood from FIG. 5, platinum generally shrinks by approximately 15% through annealing at a temperature of 775° C., but when annealing at a temperature of, for example, 500° C. is performed for preliminary crystallization, platinum shrinks by merely approximately 7% through the preliminary crystallization. Accordingly, when the regular crystallization annealing at a temperature of 775° C. is performed after the preliminary crystallization, it is presumed that the platinum shrinks by the remaining approximately 8%.

As described above, when platinum shrinks by approximately 15% at a time, the upper electrode 28 is broken (rent). However, when the annealing is once performed at a temperature of approximately 650° C. or less as the preliminary crystallization annealing and the regular crystallization annealing is performed thereafter at a general temperature of 775° C. as in Embodiment 2, the thermal shrinkage caused in the upper electrode 28 at a time can be suppressed to 10% or less, and therefore, the upper electrode 28 is not broken.

As is understood from FIG. 5, when the preliminary annealing temperature is set to approximately 400° C. or less, platinum shrinks merely by less than 5% through the preliminary annealing, and therefore, it shrinks by more than 10% in the crystallization annealing subsequently performed at a temperature of 775° C. It is presumed that the upper electrode 28 is broken in this case. Therefore, the temperature range to be employed in the preliminary crystallization annealing is preferably not less than 400° C. and not more than 650° C. and more preferably not less than 500° C. and not more than 550° C. Furthermore, the preliminary crystallization annealing may be performed over a plurality of times.

Also, although the platinum deposited by the sputtering is used as the upper electrode 28 in Embodiment 2, when the upper electrode 28 is deposited by the CVD as in Embodiment 1, the effect that the film quality of the platinum film is made dense can be additionally attained. Thus, the effect of Embodiment 2 can be further definitely exhibited.

### EMBODIMENT 3

Embodiment 3 of the invention will now be described with reference to the accompanying drawings.

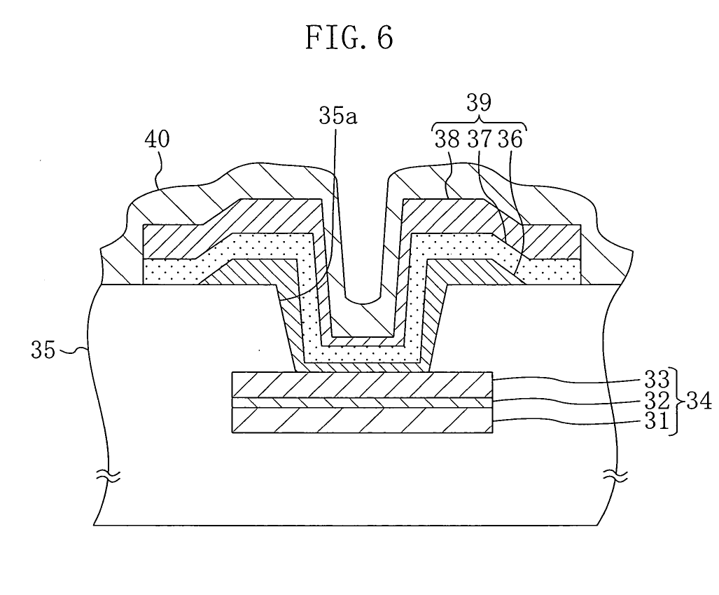

FIG. 6 shows the cross-sectional structure of a ferroelectric capacitor, that is, a semiconductor device of Embodiment 3.

As shown in FIG. 6, on a hydrogen barrier film 34 composed of, for example, a first barrier layer 31 of titanium aluminum nitride (TiAlN) with a thickness of 100 nm, a second barrier layer 32 of iridium (Ir) with a thickness of 50 nm and a third barrier layer 33 of iridium oxide (IrO₂) with a thickness of 100 nm deposited in this order in the upward direction, a capacitor 39 in a three-dimensional shape, namely, having a concave cross-section with bends in bottom and upper portions thereof, is formed.

The hydrogen barrier film 34 is buried in an underlying dielectric film 35 made of silicon oxide (SiO₂) or including silicon oxide as a principal component, and an opening 35a with a diameter of, for example, 300 nm is formed in the underlying dielectric film 35 for exposing the third barrier layer 33. The capacitor 39 includes a lower electrode 36 made of multilayered films of iridium oxide (IrO₂) with a thickness of 100 nm and platinum (Pt) with a thickness of 50 nm through 100 nm and preferably of 50 nm, a capacitor dielectric film 37 of a ferroelectric such as strontium bismuth tantalate (SBT) with a thickness of approximately 60 nm, and an upper electrode 38 of platinum with a thickness of 50 nm through 100 nm and preferably of 50 nm, which are successively deposited in this order in the upward direction so as to cover the periphery, bottom and inner wall of the opening 35a.

As a characteristic of Embodiment 3, the capacitor dielectric film 37 is subjected to crystallization annealing after forming a protecting dielectric film 40 of, for example, silicon oxide (SiO₂) with a thickness of approximately 100 nm on the upper electrode 38.

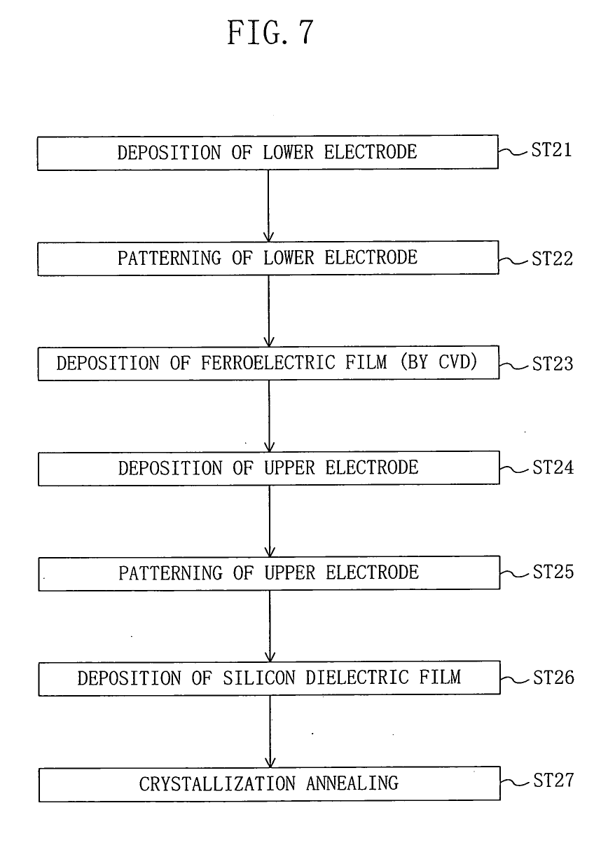

Now, a method for fabricating the ferroelectric capacitor having the aforementioned structure will be described with reference to a fabrication flowchart of FIG. 7.

First, a first barrier layer 31 of TiAlN, a second barrier layer 32 of Ir and a third barrier layer 33 of IrO₂ are successively deposited by, for example, the CVD in an upper portion of a semiconductor substrate (not shown), and these barrier layers are patterned through the dry etching using a gas including chlorine (Cl₂), so as to form a hydrogen barrier film 34 composed of the first barrier layer 31, the second barrier layer 32 and the third barrier layer 33. Subsequently, an underlying dielectric film 35 is deposited by the plasma CVD so as to cover the hydrogen barrier film 34, and an opening 35a for exposing the third barrier layer 33 is formed in the underlying dielectric film 35 through the lithography and the dry etching using an etching gas including fluorocarbon.

Next, in step ST21 of FIG. 7, a lower electrode 36 made of multilayered films of IrO₂ and Pt is deposited by the sputtering, and in step ST22, a portion of the lower electrode 36 deposited outside the periphery of the opening 35a is removed by the patterning through the lithography and the dry etching.

Then, in step ST23, a capacitor dielectric film 37 of SBT is deposited by the CVD.

Next, in step ST24, an upper electrode 38 of platinum is deposited on the capacitor dielectric film 37 by the sputtering, and thereafter, in step ST25, the deposited upper electrode 38 and capacitor dielectric film 37 are patterned through the lithography and the dry etching, resulting in obtaining a capacitor 39. At this point, the etching gas used for the upper electrode 38 is a gas including chlorine (Cl₂) and the etching gas used for the capacitor dielectric film 37 is a gas including chlorine and fluorine.

Subsequently, in step ST26, a protecting dielectric film 40 of, for example, silicon oxide with a thickness of approximately 100 nm is deposited by the CVD over the underlying dielectric film 35 including the upper electrode 38. At this point, the deposition temperature is approximately 550° C.

Then, in step ST27, the capacitor 39 is subjected to annealing at a temperature of approximately 775° C. in an oxygen atmosphere for 60 seconds, so as to crystallize the SBT included in the capacitor dielectric film 37.

Now, the reason why the upper electrode 38 is covered with the protecting dielectric film 40 before the crystallization annealing in Embodiment 3 will be described.

First, since the protecting dielectric film 40 is deposited at a temperature of approximately 550° C., the upper electrode 38 is substantially subjected to preliminary crystallization annealing. When the preliminary crystallization annealing is performed, the upper electrode 38 can be prevented from being broken (rent) as in Embodiment 2.

Secondly, when the platinum film of the upper electrode 38 is covered with the protecting dielectric film 40, the thermal shrinkage of the platinum film can be physically suppressed.

Owing to these two effects, the upper electrode 38 can be more effectively prevented from being broken than in Embodiment 2.

Although the platinum deposited by the sputtering is used as the upper electrode 38 in Embodiment 3, when the upper electrode 38 is deposited by the CVD as in Embodiment 1, the effect that the film quality of the platinum film is made dense can be additionally attained. Thus, the effect of Embodiment 3 can be further definitely exhibited.

Furthermore, although the protecting dielectric film 40 used for protecting the upper electrode 38 is made of silicon oxide in Embodiment 3, the material of the protecting dielectric film 40 is not limited to silicon oxide but the same effect can be attained by using silicon oxinitride or silicon nitride.

In each of Embodiments 1 through 3, the cross-sectional structure of the capacitor and the like is what is called a concave type structure in which a capacitor and the like are formed in the concave of an underlying dielectric film or the like. However, similar effects can be attained also when the structure is what is called a column type structure in which a columnar lower electrode is formed on a flat underlying dielectric film and a capacitor dielectric film of a ferroelectric and an upper electrode are formed on the side and upper faces of the lower electrode.

Although the ferroelectric used in the capacitor dielectric film is SBT, namely, SrBi₂Ta₂O₉, in each embodiment, the SBT may be replaced with strontium bismuth tantalate niobate (SrBi₂(TaₓNb₁₋ₓ)₂O₉), lead zirconate titanate (Pb(ZrₓTi₁₋ₓ)O₃), barium strontium titanate ((BaₓSr₁₋ₓ)TiO₃) or bismuth lanthanum titanate ((BiₓLa₁₋ₓ)₄Ti₃O₁₂) (in all of which 0≦x≦1).

Furthermore, the material of the capacitor dielectric film may be a metal oxide and hence is not limited to a ferroelectric but may be a high dielectric constant material such as tantalum pentoxide (Ta₂O₅).

Moreover, although the capacitor dielectric film is deposited by the CVD in each embodiment, the deposition method is not limited to the CVD as far as the capacitor dielectric film can be deposited at high coverage even on a portion with a level difference.

Additionally, although platinum is used for the lower electrode and the upper electrode in each embodiment, the platinum may be replaced with another platinum group element, such as ruthenium (Ru), rhodium (Rh), palladium (Pd), osmium (Os) or iridium (Ir). Each of the lower electrode and the upper electrode preferably has a thickness of approximately 50 nm through 100 nm.

As described so far, the semiconductor device and the method for fabricating the same of this invention exhibit the effect to prevent break (rent) of an upper electrode otherwise caused in deposition of a ferroelectric capacitor in a three-dimensional shape, and hence are useful for fabricating a semiconductor device including a ferroelectric capacitor in a three-dimensional shape.

1. A semiconductor device comprising:
a lower electrode having a bend in a cross-section thereof;
a capacitor dielectric film made of a ferroelectric formed along a top face of said lower electrode; and
an upper electrode formed along a top face of said capacitor dielectric film,
wherein said upper electrode is formed by chemical vapor deposition.

2. The semiconductor device of claim 1,
wherein said capacitor dielectric film is formed by chemical vapor deposition.

3. A method for fabricating a semiconductor device comprising the steps of:
forming an underlying film having a concave or convex on a top face thereof;
forming a lower electrode on said underlying film along said concave or convex;
forming a capacitor dielectric film made of a ferroelectric on and along said lower electrode; and
forming an upper electrode by chemical vapor deposition on and along said capacitor dielectric film.

4. The method for fabricating a semiconductor device of claim 3,
wherein said capacitor dielectric film is formed by chemical vapor deposition.

5. The method for fabricating a semiconductor device of claim 3,
wherein said upper electrode is made of platinum and deposited at a temperature not less than 300° C. in the step of forming an upper electrode.

6. The method for fabricating a semiconductor device of claim 3,
wherein said ferroelectric is SrBi₂(TaₓNb₁₋ₓ)₂O₉, Pb(ZrₓTi₁₋ₓ)O₃, (BaₓSr₁₋ₓ)TiO₃ or (BiₓLa₁₋ₓ)₄Ti₃O₁₂, wherein 0≦x≦1.

7. A method for fabricating a semiconductor device comprising the steps of:
forming an underlying film having a concave or convex on a top face thereof;
forming a lower electrode on said underlying film along said concave or convex;
forming a capacitor dielectric film made of a ferroelectric on and along said lower electrode;
forming an upper electrode on and along said capacitor dielectric film; and
crystallizing said capacitor dielectric film in a stepwise manner through a plurality of times of annealing of said capacitor dielectric film after forming said upper electrode.

8. The method for fabricating a semiconductor device of claim 7,
wherein annealing first performed out of said plurality of times of annealing in the step of crystallizing said capacitor dielectric film in a stepwise manner is performed at a temperature not less than 400° C. and not more than 650° C.

9. The method for fabricating a semiconductor device of claim 7,
wherein said ferroelectric is SrBi₂(TaₓNb₁₋ₓ)₂O₉, Pb(ZrₓTi₁₋ₓ)O₃, (BaₓSr₁₋ₓ)TiO₃ or (BiₓLa₁₋ₓ)₄Ti₃O₁₂, wherein 0≦x≦1.

10. A method for fabricating a semiconductor device comprising the steps of:
forming an underlying film having a concave or convex on a top face thereof;
forming a lower electrode on said underlying film along said concave or convex;
forming a capacitor dielectric film made of a ferroelectric on and along said lower electrode;
forming an upper electrode on and along said capacitor dielectric film;
forming a dielectric film including silicon on said upper electrode; and
crystallizing said capacitor dielectric film through annealing of said capacitor dielectric film after forming said dielectric film.

11. The method for fabricating a semiconductor device of claim 10,
wherein said dielectric film is deposited at a temperature not less than 400° C. and not more than 650° C. in the step of forming a dielectric film including silicon.

12. The method for fabricating a semiconductor device of claim 10, wherein said ferroelectric is SrBi₂(TaₓNb₁₋ₓ)₂O₉, Pb(ZrₓTi₁₋ₓ)O₃, (BaₓSr₁₋ₓ)TiO₃ or (BiₓLa₁₋ₓ)₄Ti₃O₁₂, wherein 0≦x≦1.
